(19) United States
(12) Patent Application Publication
(10) Pub. No.: US 2026/0367500 A1
(43) Pub. Date: Nov. 19, 2026

(54) MASK FOR FORMING TARGET PATTERN AND METHOD OF FORMING THE SAME

(71) Applicant: United Microelectronics Corp., Hsinchu (TW)

(72) Inventors: Yi Lin Tsai, Tainan City (TW); Chih-Hsien Tang, Taipei City (TW)

(73) Assignee: United Microelectronics Corp., Hsinchu (TW)

(21) Appl. No.: 19/238,499

(22) Filed: Jun. 15, 2025

(30) Foreign Application Priority Data
May 16, 2025 (TW) 114118405

(51) Int. Cl. G03F 1/38

(52) U.S. Cl. CPC G03F 1/38

(57) ABSTRACT

Provided are a mask for forming a target pattern and a method of forming the same. The mask for forming the target pattern includes a mask pattern. The mask pattern includes the target pattern having multiple corners and multiple first compensation patterns. Each of the multiple first compensation patterns relatively overlaps with each of the multiple corners of the target pattern. A first center opposite side axis of each of the multiple first compensation patterns is coaxial with a relative first center corner axis of the target pattern. The first center opposite side axis passes through an opposite side center of an opposite side of the first compensation pattern and a pattern center of the first compensation pattern. The opposite side of the first compensation pattern does not contact the target pattern.

### CROSS-REFERENCE TO RELATED APPLICATION

This application claims the priority benefit of Taiwan application serial no. 114118405, filed on May 16, 2025. The entirety of the above-mentioned patent application is hereby incorporated by reference herein and made a part of this specification.

### BACKGROUND

### Technical Field

The disclosure relates to a mask for forming a target pattern, and particularly relates to a mask for forming a target pattern and a method of forming the same.

### Related Art

In the trend of increasingly precise semiconductor manufacturing, due to the limitations of optical properties, after a target pattern has been pattern transferred through a lithography process, there is often a problem of rounding at the corners of the transferred pattern. The phenomenon is referred to as the corner rounding effect.

The corner rounding phenomenon may cause differences between the transferred pattern and the target pattern, increasing a value of a mask error enhancement factor (MEEF), and especially generating a negative impact on critical components with stringent critical dimension (CD) demands.

Therefore, it is needed to utilize various correction ways to allow the transferred pattern to be closer to the desired target pattern.

### SUMMARY

Based on the foregoing problem, the disclosure provides a mask for forming a target pattern and a method of forming the same, allowing a transferred pattern to be closer to the desired target pattern.

An embodiment of the disclosure provides a mask for forming a target pattern, which includes: a mask pattern, which includes: a target pattern that has multiple corners; and multiple first compensation patterns. Each of the multiple first compensation patterns relatively overlaps with each of the multiple corners of the target pattern. A first center opposite side axis of each of the multiple first compensation patterns is coaxial with a relative first center corner axis of the target pattern. The first center opposite side axis passes through an opposite side center of an opposite side of the first compensation pattern and a pattern center of the first compensation pattern. The opposite side of the first compensation pattern does not contact the target pattern. The first center corner axis passes through one of the multiple corners of the target pattern and a pattern center of the target pattern.

In some embodiments, the target pattern includes a polygon.

In some embodiments, each of the multiple first compensation patterns includes a rectangle.

In some embodiments, an area of each of the multiple first compensation patterns is smaller than an area of the target pattern.

In some embodiments, a length of the opposite side of each of the multiple first compensation patterns is 8% to 30% of a side length of the target pattern.

In some embodiments, 5% to 20% of an area of each of the multiple first compensation patterns overlaps with the target pattern.

In some embodiments, multiple second compensation patterns are further included. Each of the multiple second compensation patterns is correspondingly connected with each of the multiple first compensation patterns. A second center opposite side axis of each of the multiple second compensation patterns is coaxial with the first center opposite side axis of each of the corresponding multiple first compensation patterns. The second center opposite side axis passes through an opposite side center of an opposite side of the second compensation pattern and a pattern center of the second compensation pattern. The opposite side of the second compensation pattern does not contact the first compensation pattern.

In some embodiments, each of the multiple second compensation patterns includes a rectangle.

In some embodiments, an area of each of the multiple second compensation patterns is smaller than an area of each of the multiple first compensation patterns.

In some embodiments, a length of the opposite side of each of the multiple second compensation patterns is 25% to 80% of a length of the opposite side of each of the multiple first compensation patterns.

An embodiment of the disclosure provides a method of forming a mask for forming a target pattern, which includes: forming a mask pattern, which includes: providing a target pattern that has multiple corners; and forming multiple first compensation patterns. Each of the multiple first compensation patterns relatively overlaps with each of the multiple corners of the target pattern. A first center opposite side axis of each of the multiple first compensation patterns is coaxial with a relative first center corner axis of the target pattern. The first center opposite side axis passes through an opposite side center of an opposite side of the first compensation pattern and a pattern center of the first compensation pattern. The opposite side of the first compensation pattern does not contact the target pattern. The first center corner axis passes through one of the multiple corners of the target pattern and a pattern center of the target pattern.

In some embodiments, the target pattern includes a polygon.

In some embodiments, each of the multiple first compensation patterns includes a rectangle.

In some embodiments, an area of each of the multiple first compensation patterns is smaller than an area of the target pattern.

In some embodiments, a length of the opposite side of each of the multiple first compensation patterns is 8% to 30% of a side length of the target pattern.

In some embodiments, 5% to 20% of an area of each of the multiple first compensation patterns overlaps with the target pattern.

In some embodiments, forming multiple second compensation patterns is further included. Each of the multiple second compensation patterns is correspondingly connected with each of the multiple first compensation patterns. A second center opposite side axis of each of the multiple second compensation patterns is coaxial with the first center opposite side axis of each of the corresponding multiple first compensation patterns. The second center opposite side axis passes through an opposite side center of an opposite side of the second compensation pattern and a pattern center of the second compensation pattern. The opposite side of the second compensation pattern does not contact the first compensation pattern.

In some embodiments, each of the multiple second compensation patterns includes a rectangle.

In some embodiments, an area of each of the multiple second compensation patterns is smaller than an area of each of the multiple first compensation patterns.

In some embodiments, a length of the opposite side of each of the multiple second compensation patterns is 25% to 80% of a length of the opposite side of each of the multiple first compensation patterns.

Based on the above, the disclosure provides the mask for forming the target pattern and the method of forming the same. By the manner of forming a specific compensation pattern at the corners of the target pattern, the corner rounding effect of a final pattern can be effectively reduced, allowing a value of a mask error enhancement factor (MEEF) to decrease, and allowing a pattern transferred by a corrected mask to be closer to the target pattern.

In addition, since the disclosure is that a center opposite side axis of a compensation pattern is coaxially arranged with a center corner axis of the target pattern, the center opposite side axis of the compensation pattern refers to an axis passing through an opposite side center of an opposite side of the compensation pattern and a pattern center of the compensation pattern, the opposite side of the compensation pattern does not contact the target pattern, and the center corner axis of the target pattern refers to an axis passing through a corner of the target pattern and a pattern center of the target pattern, the arrangement of the compensation pattern allows each corner of the target pattern to change from five vertices of an orthogonal OPC (optical proximity correction) serif to only four vertices. A corner pattern of the four vertices has a smaller MEEF after pattern transfer compared to a corner pattern having the five vertices, representing that a pattern transfer process is less affected by mask process errors.

In order to make the features and advantages of the disclosure more comprehensible, the following examples are given and described in detail with the accompanying drawings as follows.

### BRIEF DESCRIPTION OF THE DRAWINGS

FIG. 1A is a target pattern according to Embodiment 1 and Embodiment 2 of the disclosure.

FIG. 1B is a schematic diagram of a mask for forming a target pattern according to Embodiment 1 of the disclosure.

FIG. 2 is a schematic diagram of a mask for forming a target pattern according to Embodiment 2 of the disclosure.

FIG. 3A is a target pattern according to Embodiment 3 of the disclosure.

FIG. 3B is a schematic diagram of a mask for forming a target pattern according to Embodiment 3 of the disclosure.

### DESCRIPTION OF THE EMBODIMENTS

The embodiments are described in detail below with reference to the accompanying drawings, but the embodiments are not intended to limit the scope of the disclosure. In addition, the drawings are for illustrative purposes only and are not drawn to the original dimensions. For ease of understanding, the same elements in the following description are denoted by the same reference symbols, which will not be elaborated repeatedly in the following paragraphs.

In the text, the terms mentioned in the text, such as “comprising”, “including”, “containing” and “having” are all open-ended terms, i.e., meaning “including but not limited to”.

In addition, the directional terms, such as “on”, “above”, “under” and “below” mentioned in the text are only used to refer to the direction of the drawings, and are not used to limit the disclosure.

As used herein, “about,” “approximately” or “substantially” includes the values as mentioned and the average values within the range of acceptable deviations that can be determined by those of ordinary skill in the art. Consider to the specific amount of errors related to the measurements (that is, the limitations of the measurement system), the meaning of “about” may be, for example, referred to a value within one or more standard deviations of the value, or within ±30%, ±20%, ±10%, ±5%. Furthermore, the “about,” “approximately” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

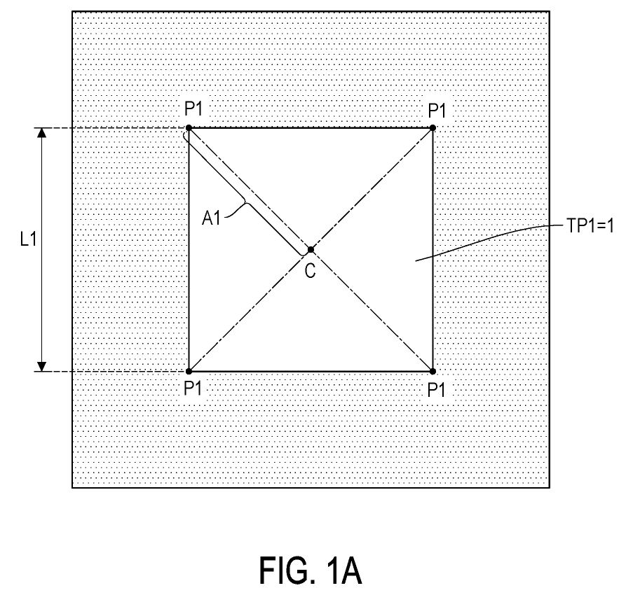

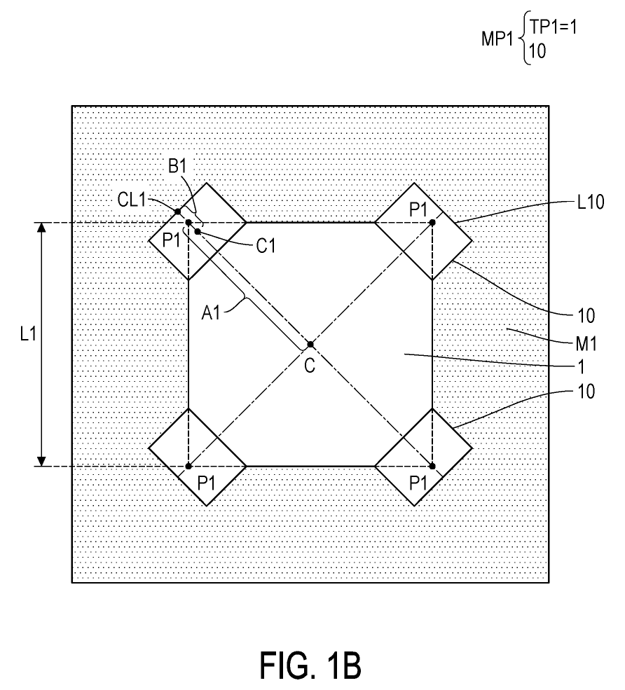

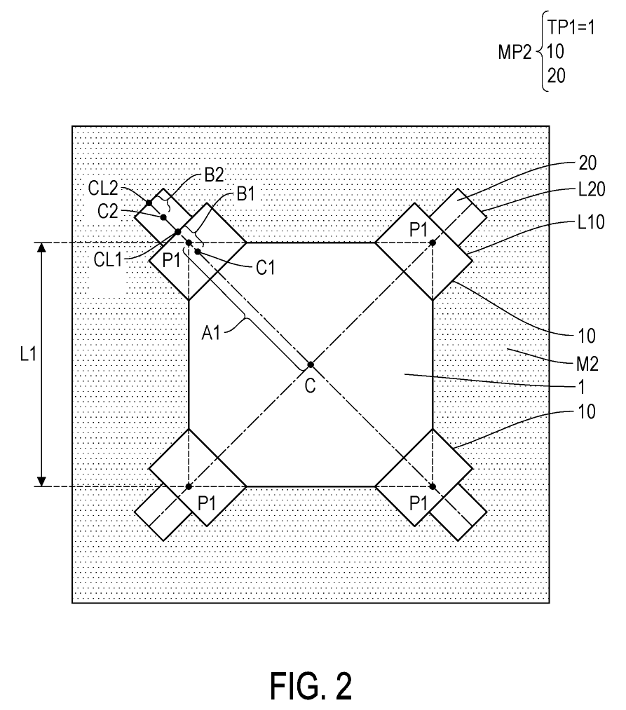

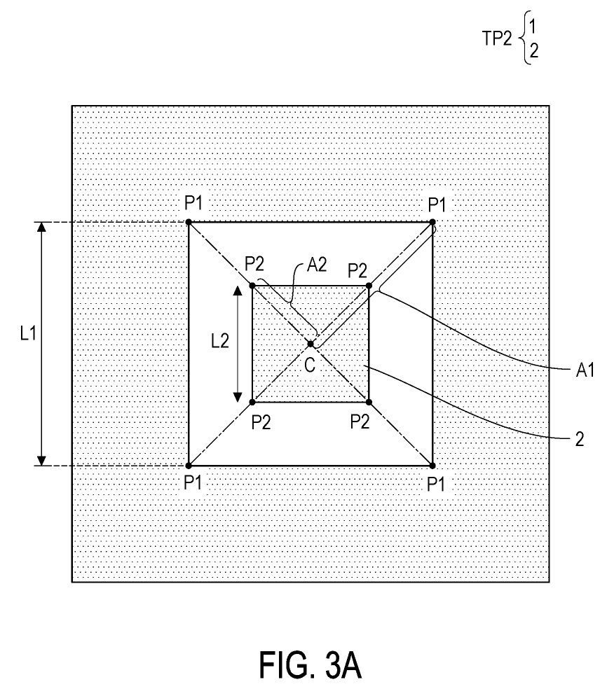

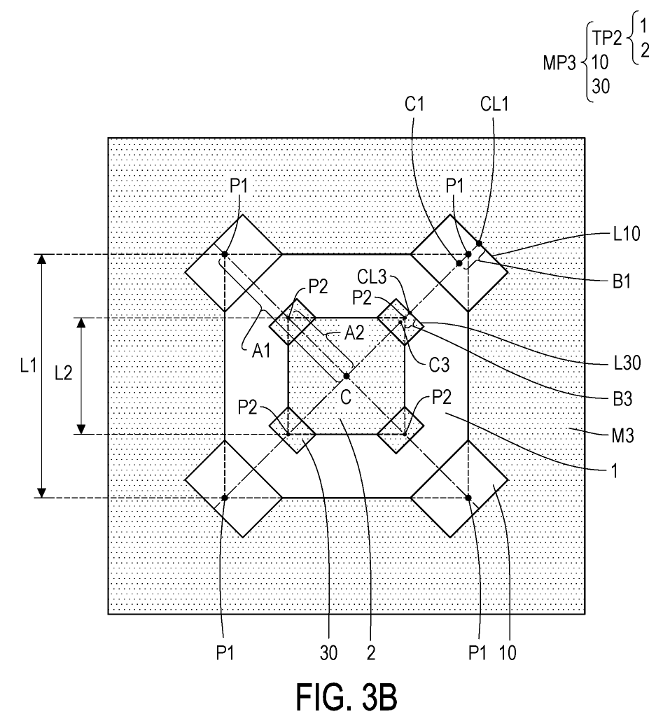

For a mask for forming a target pattern and a method of forming the same of the disclosure, please refer to the following Embodiment 1 to Embodiment 3. Please understand in conjunction with FIG. 1A which is a target pattern according to Embodiment 1 and Embodiment 2 of the disclosure, FIG. 1B which is a schematic diagram of a mask for forming a target pattern according to Embodiment 1 of the disclosure, FIG. 2 which is a schematic diagram of a mask for forming a target pattern according to Embodiment 2 of the disclosure, FIG. 3A which is a target pattern according to Embodiment 3 of the disclosure, and FIG. 3B which is a schematic diagram of a mask for forming a target pattern according to Embodiment 3 of the disclosure. Moreover, these figures are only for the purpose of description and are not intended to limit the scope of the disclosure.

### Embodiment 1

The disclosure provides a mask M1 for forming a target pattern TP1 and a method of forming the same. The target pattern TP1 has multiple corners P1, as shown in FIG. 1A.

In some embodiments, the target pattern TP1 may include a polygon, such as a triangle, a rectangle, a pentagon, a hexagon, etc. However, the disclosure is not limited thereto. The rectangle may include a square or a rectangle (not shown), etc. For example, as shown in FIG. 1A, a first rectangle 1 is a square with a side length of L1. However, the disclosure is not limited thereto.

Please continue to refer to FIG. 1A. The multiple corners P1 of the target pattern TP1 may respectively form a first center corner axis A1 of the target pattern TP1 with a pattern center C of the target pattern TP1. That is, as shown in FIG. 1A, the multiple corners P1 of the first rectangle 1 may respectively form the first center corner axis A1 of the first rectangle 1 with the pattern center C of the first rectangle 1.

Next, please refer to FIG. 1B. A method of forming the mask M1 for forming the target pattern TP1 includes forming a mask pattern MP1. A formation of the mask pattern MP1 includes providing the target pattern TP1 having the multiple corners P1 and forming multiple first compensation patterns 10. Each of the multiple first compensation patterns 10 relatively overlaps with each of the multiple corners P1 of the target pattern TP1. A first center opposite side axis B1 of each of the multiple first compensation patterns 10 is coaxial with a relative corresponding first center corner axis A1 of the target pattern TP1. That is, the first center opposite side axis B1 of each of the multiple first compensation patterns 10 and the relative first center corner axis A1 of the target pattern TP1 are located on a same extension line. The first center opposite side axis B1 passes through an opposite side center CL1 of an opposite side L10 of the first compensation pattern 10 and a pattern center C1 of the first compensation pattern 10. The opposite side L10 of the first compensation pattern 10 does not contact the target pattern TP1. The first center corner axis A1 passes through one of the multiple corners P1 of the target pattern TP1 and the pattern center C of the target pattern TP1.

In some embodiments, each of the multiple first compensation patterns 10 may include a rectangle. The rectangle may include a square or a rectangle, etc. However, the disclosure is not limited thereto.

In some embodiments, an area of each of the multiple first compensation patterns 10 is smaller than an area of the target pattern TP1.

In some embodiments, a side length of the opposite side L10 of each of the multiple first compensation patterns 10 may be 8% to 30% of a side length L1 of the target pattern TP1. The opposite side L10 of each of the multiple first compensation patterns 10 may not violate a mask manufacturing limit. That is, the opposite side L10 of each of the multiple first compensation patterns 10 needs to be greater than the mask manufacturing limit.

In some embodiments, 5% to 20% of an area of each of the multiple first compensation patterns 10 overlaps with the target pattern TP1. The area of each of the multiple first compensation patterns 10 may not be too small. A side length of each side may not violate the mask manufacturing limit. That is, the side length of each side of each of the multiple first compensation patterns 10 needs to be greater than the mask manufacturing limit.

As mentioned above, as shown in FIG. 1A, the target pattern TP1 includes the first rectangle 1. By utilizing the manner of Embodiment 1, the multiple first compensation patterns 10 are formed at each of the multiple corners P1 of the first rectangle 1, as shown in FIG. 1B, to form the mask M1 for forming the target pattern TP1. Actually, the concept of the disclosure also includes forming a mask of a target pattern including the multiple first rectangles 1 with the target pattern having the multiple first rectangles 1 in the manner described in Embodiment 1 where the multiple first compensation patterns 10 are added to each of the first rectangles 1. For example, a mask of a target pattern including the multiple first rectangles 1 is formed with the target pattern including the multiple first rectangles 1 arranged in a matrix through the manner described in Embodiment 1 where the multiple first compensation patterns 10 are added to each of the first rectangles 1 arranged in a matrix. However, the concept of the disclosure is not limited thereto, but further includes mask patterns with various other arrangement manners.

### Embodiment 2

Based on the technical features described in Embodiment 1, as needed, a corresponding second compensation pattern 20 may be added to each of the multiple corners P1 of the target pattern TP1, as shown in FIG. 2.

That is to say, Embodiment 2 is a mask M2 for forming the same target pattern TP1 as Embodiment 1 and a method of forming the same. A mask pattern MP2 of the mask M2 of Embodiment 2 includes not only the target pattern TP1 and the multiple first compensation patterns 10, but also includes the multiple second compensation patterns 20. Each of the multiple second compensation patterns 20 is correspondingly connected with each of the multiple first compensation patterns 10. A second center opposite side axis B2 of each of the multiple second compensation patterns 20 is coaxial with the first center opposite side axis B1 of each of the multiple first compensation patterns 10. That is, the second center opposite side axis B2 of each of the multiple second compensation patterns 20 and the first center opposite side axis B1 of each of the multiple first compensation patterns 10 are located on a same extension line. The second center opposite side axis B2 passes through an opposite side center CL2 of an opposite side L20 of the second compensation pattern 20 and a pattern center C2 of the second compensation pattern 20. The opposite side L20 of the second compensation pattern 20 does not contact the first compensation pattern 10, as shown in FIG. 2.

As described in Embodiment 1, since the first center opposite side axis B1 of each of the multiple first compensation patterns 10 is coaxial with the first center corner axis A1 of the corresponding target pattern TP1, and as mentioned above, the second center opposite side axis B2 of each of the multiple second compensation patterns 20 is coaxial with the first center opposite side axis B1 of each of the multiple first compensation patterns 10, the second center opposite side axis B2 of each of the multiple second compensation patterns 20 may also be coaxial with the first center corner axis A1 of the corresponding target pattern TP1.

In some embodiments, each of the multiple second compensation patterns 20 may be a rectangle. The rectangle may include a square or a rectangle, etc. However, the disclosure is not limited thereto.

In some embodiments, an area of each of the multiple second compensation patterns 20 is smaller than an area of each of the multiple first compensation patterns 10.

In some embodiments, a length of the opposite side L20 of each of the multiple second compensation patterns 20 may be 25% to 80% of a length of the opposite side L10 of each of the multiple first compensation patterns 10. A side length of each side of each of the multiple second compensation patterns 20 may not violate the mask manufacturing limit. That is, the side length of each side of each of the multiple second compensation patterns 20 needs to be greater than the mask manufacturing limit.

As mentioned above, as shown in FIG. 1A, the target pattern TP1 includes the first rectangle 1. By utilizing the manner of Embodiment 2, the multiple first compensation patterns 10 and the multiple second compensation patterns 20 are respectively formed at the multiple corners P1 of the first rectangle 1, as shown in FIG. 2, to form the mask M2 for forming the target pattern TP1. Actually, the concept of the disclosure also includes forming a mask of a target pattern including the multiple first rectangles 1 with the target pattern having the multiple rectangles 1 in the manner described in Embodiment 2 where the first compensation patterns 10 and the multiple second compensation patterns 20 are added to each of the first rectangles 1. For example, forming a mask of a target pattern including the multiple first rectangles 1 with the target pattern including the multiple first rectangles 1 arranged in a matrix through the manner described in Embodiment 2 where the multiple first compensation patterns 10 and the multiple second compensation patterns 20 are added to each of the first rectangles 1 arranged in a matrix. However, the concept of the disclosure is not limited thereto, but further includes mask patterns with various other arrangement manners.

Moreover, the concept of the disclosure is not limited to the manner described in Embodiment 2 of adding the multiple first compensation patterns 10 and the multiple second compensation patterns 20 to each of the first rectangles 1, but rather, as needed, utilizing the manners of Embodiment 1 and Embodiment 2 to continue to successively add compensation patterns such as multiple third compensation patterns, multiple fourth compensation patterns, etc. at the multiple corners P1 of the first rectangle 1 to allow a final pattern to be closer to the target pattern.

### Embodiment 3

The disclosure provides a mask M3 for forming a target pattern TP2 and a method of forming the same. In addition to the first rectangle 1 described in Embodiment 1 and Embodiment 2, the target pattern TP2 may also include other patterns in the first rectangle 1. The other pattern may include a polygon, such as a triangle, a rectangle, a pentagon, a hexagon, etc. However, the disclosure is not limited thereto. The rectangle may include a square or a rectangle (not shown), etc. For example, as shown in FIG. 3A, the target pattern TP2 includes the first rectangle 1 described in Embodiment 1 and Embodiment 2 and a second rectangle 2 located in the first rectangle 1.

Moreover, the second rectangle 2 is an inverted pattern of the first rectangle 1. For example, the first rectangle 1 is a light-transmitting pattern, while the second rectangle 2 is a non-light-transmitting pattern, as shown in FIG. 3A. Alternatively, the first rectangle 1 is a non-light-transmitting pattern, while the second rectangle 2 is a light-transmitting pattern.

Please continue to refer to FIG. 3A. The first rectangle 1 may include a square with the side length L1 and the pattern center C. The first rectangle 1 has the multiple corners P1 and the first center corner axis A1 respectively connected to the pattern center C, as described in Embodiment 1, which will not be repeated here.

Please continue to refer to FIG. 3A. The second rectangle 2 may include a square with a side length L2 and the pattern center C. The second rectangle 2 has multiple corners P2 and a second center corner axis A2 respectively connected to the pattern center C.

The first rectangle 1 and the second rectangle 2 shown in FIG. 3A have the same pattern center C. However, the disclosure is not limited thereto. The first rectangle 1 and the second rectangle 2 may also have different pattern centers.

Next, please refer to FIG. 3B. The same concept as Embodiment 1 may be utilized to form the multiple first compensation patterns 10 at the multiple corners P1 of the corresponding first rectangle 1. Technical features such as formation locations and dimensions of the multiple first compensation patterns 10, as described in Embodiment 1, will not be repeated here.

By utilizing the same concept as Embodiment 1, multiple third compensation patterns 30 are formed at the multiple corners P2 of the corresponding second rectangle 2, as shown in FIG. 3B. Each of the multiple third compensation patterns 30 relatively overlaps with each of the multiple corners P2 of the second rectangle 2. A third center opposite side axis B3 of each of the multiple third compensation patterns 30 is coaxial with the second center corner axis A2 of the corresponding second rectangle 2. That is, the third center opposite side axis B3 of each of the multiple third compensation patterns 30 and the second center corner axis A2 of the corresponding second rectangle 2 are located on a same extension line. The third center opposite side axis B3 passes through an opposite side center CL3 of an opposite side L30 of the third compensation pattern 30 and a pattern center C3 of the third compensation pattern 30. The opposite side L30 of the third compensation pattern 30 does not contact the second rectangle 2. The second center corner axis A2 passes through the corner P2 of the second rectangle 1 and the pattern center C of the second rectangle 1.

In some embodiments, each of the multiple third compensation patterns 30 may be a rectangle. The rectangle may include a square or a rectangle, etc. However, the disclosure is not limited thereto.

In some embodiments, an area of each of the multiple third compensation patterns 30 is smaller than an area of the second rectangle 2.

In some embodiments, a side length of the opposite side L30 of each of the multiple third compensation patterns 30 may be 8% to 30% of the side length L2 of the second rectangle 2. The opposite side L30 of each of the multiple third compensation patterns 30 may not violate the mask manufacturing limit. That is, the opposite side L30 of each of the multiple third compensation patterns 30 needs to be greater than the mask manufacturing limit.

In some embodiments, 5% to 20% of an area of each of the multiple third compensation patterns 30 overlaps with the second rectangle 2. The area of each of the multiple third compensation patterns 30 may not be too small. A side length of each side may not violate the mask manufacturing limit. That is, the side length of each side of each of the multiple third compensation patterns 30 needs to be greater than the mask manufacturing limit.

As mentioned above, as shown in FIG. 3A, the target pattern TP2 includes the first rectangle 1 and the second rectangle 2 located inside the first rectangle 1. By utilizing the manner of Embodiment 3, the multiple first compensation patterns 10 are respectively formed at the multiple corners P1 of the first rectangle 1, and the multiple third compensation patterns 30 are respectively formed at the multiple corners P2 of the second rectangle 2, as shown in FIG. 3B, to form the mask M3 for forming the target pattern TP2. Actually, the concept of the disclosure also includes forming a mask of a target pattern including the multiple first rectangles 1 and the multiple second rectangles 2 with the target pattern having the multiple first rectangles 1 and the multiple second rectangles 2 in the manner described in Embodiment 3 where the multiple first compensation patterns 10 are added to each of the first rectangles 1, and the multiple third compensation patterns 30 are added to each of the second rectangles 2. For example, forming a mask of a target pattern including the multiple first rectangles 1 and the multiple second rectangles 2a with the target pattern including the multiple first rectangles 1 and the multiple second rectangles 2 arranged in a matrix through the manner described in Embodiment 3 where the multiple first compensation patterns 10 are added to each of the first rectangles 1 arranged in a matrix, and the multiple third compensation patterns 30 are added to each of the first rectangles 2 arranged in a matrix. However, the concept of the disclosure is not limited thereto, but further includes mask patterns with various other arrangement manners.

By utilizing the manner of forming a specific compensation pattern at the corners of the target pattern as described above, the corner rounding effect of a final pattern can be effectively reduced, allowing a value of a mask error enhancement factor (MEEF) to decrease, and allowing a pattern transferred by a corrected mask to be closer to the target pattern.

In addition, since the disclosure is that a center opposite side axis of a compensation pattern is coaxially arranged with a center corner axis of the target pattern, the center opposite side axis of the compensation pattern refers to an axis passing through an opposite side center of an opposite side of the compensation pattern and a pattern center of the compensation pattern, the opposite side of the compensation pattern does not contact the target pattern, and the center corner axis of the target pattern refers to an axis passing through a corner of the target pattern and a pattern center of the target pattern, the arrangement of the compensation pattern allows each corner of the target pattern to change from five vertices of an orthogonal OPC (optical proximity correction) serif to only four vertices. A corner patterns of the four vertices has a smaller MEEF after pattern transfer compared to a corner pattern having the five vertices, representing that a pattern transfer process is less affected by mask process errors.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A mask for forming a target pattern, comprising:
a mask pattern, comprising:
a target pattern, having a plurality of corners; and
a plurality of first compensation patterns, wherein
each of the plurality of first compensation patterns relatively overlaps with each of the plurality of corners of the target pattern, and
a first center opposite side axis of each of the plurality of first compensation patterns is coaxial with a relative first center corner axis of the target pattern, wherein the first center opposite side axis passes through an opposite side center of an opposite side of the first compensation pattern and a pattern center of the first compensation pattern, wherein the opposite side of the first compensation pattern does not contact the target pattern, and wherein the first center corner axis passes through one of the plurality of corners of the target pattern and a pattern center of the target pattern.

2. The mask for forming the target pattern according to claim 1, wherein the target pattern comprises a polygon.

3. The mask for forming the target pattern according to claim 1, wherein each of the plurality of first compensation patterns comprises a rectangle.

4. The mask for forming the target pattern according to claim 1, wherein an area of each of the plurality of first compensation patterns is smaller than an area of the target pattern.

5. The mask for forming the target pattern according to claim 1, wherein a length of the opposite side of each of the plurality of first compensation patterns is 8% to 30% of a side length of the target pattern.

6. The mask for forming the target pattern according to claim 1, wherein 5% to 20% of an area of each of the plurality of first compensation patterns overlaps with the target pattern.

7. The mask for forming the target pattern according to claim 1, further comprising a plurality of second compensation patterns, wherein
each of the plurality of second compensation patterns is correspondingly connected with each of the plurality of first compensation patterns, and
a second center opposite side axis of each of the plurality of second compensation patterns is coaxial with the first center opposite side axis of each of the corresponding plurality of first compensation patterns, wherein the second center opposite side axis passes through an opposite side center of an opposite side of the second compensation pattern and a pattern center of the second compensation pattern, wherein the opposite side of the second compensation pattern does not contact the first compensation pattern.

8. The mask for forming the target pattern according to claim 7, wherein each of the plurality of second compensation patterns comprises a rectangle.

9. The mask for forming the target pattern according to claim 7, wherein an area of each of the plurality of second compensation patterns is smaller than an area of each of the plurality of first compensation patterns.

10. The mask for forming the target pattern according to claim 7, wherein a length of the opposite side of each of the plurality of second compensation patterns is 25% to 80% of a length of the opposite side of each of the plurality of first compensation patterns.

11. A method of forming a mask for forming a target pattern, comprising:
forming a mask pattern, comprising:
providing a target pattern, having a plurality of corners; and
forming a plurality of first compensation patterns, wherein
each of the plurality of first compensation patterns relatively overlaps with each of the plurality of corners of the target pattern, and
a first center opposite side axis of each of the plurality of first compensation patterns is coaxial with a relative first center corner axis of the target pattern, wherein the first center opposite side axis passes through an opposite side center of an opposite side of the first compensation pattern and a pattern center of the first compensation pattern, wherein the opposite side of the first compensation pattern does not contact the target pattern, and wherein the first center corner axis passes through one of the plurality of corners of the target pattern and a pattern center of the target pattern.

12. The method of forming the mask for forming the target pattern according to claim 11, wherein the target pattern comprises a polygon.

13. The method of forming the mask for forming the target pattern according to claim 11, wherein each of the plurality of first compensation patterns comprises a rectangle.

14. The method of forming the mask for forming the target pattern according to claim 11, wherein an area of each of the plurality of first compensation patterns is smaller than an area of the target pattern.

15. The method of forming the mask for forming the target pattern according to claim 11, wherein a length of the opposite side of each of the plurality of first compensation patterns is 8% to 30% of a side length of the target pattern.

16. The method of forming the mask for forming the target pattern according to claim 11, wherein 5% to 20% of an area of each of the plurality of first compensation patterns overlaps with the target pattern.

17. The method of forming the mask for forming the target pattern according to claim 11, further comprising forming a plurality of second compensation patterns, wherein
each of the plurality of second compensation patterns is correspondingly connected with each of the plurality of first compensation patterns, and
a second center opposite side axis of each of the plurality of second compensation patterns is coaxial with the first center opposite side axis of each of the corresponding plurality of first compensation patterns, wherein the second center opposite side axis passes through an opposite side center of an opposite side of the second compensation pattern and a pattern center of the second compensation pattern, wherein the opposite side of the second compensation pattern does not contact the first compensation pattern.

18. The method of forming the mask for forming the target pattern according to claim 17, wherein each of the plurality of second compensation patterns comprises a rectangle.

19. The method of forming the mask for forming the target pattern according to claim 17, wherein an area of each of the plurality of second compensation patterns is smaller than an area of each of the plurality of first compensation patterns.

20. The method of forming the mask for forming the target pattern according to claim 17, wherein a length of the opposite side of each of the plurality of second compensation patterns is 25% to 80% of a length of the opposite side of each of the plurality of first compensation patterns.
